(19) United States
(12) Patent Application Publication
(10) Pub. No.: US 2025/0201300 A1
(43) Pub. Date: Jun. 19, 2025

(54) LOW-POWER STATIC RANDOM ACCESS MEMORY

(71) Applicant: UNTETHER AI CORPORATION, Toronto (CA)

(72) Inventors: Katsuyuki SATO, Tokyo (JP); William Martin SNELGROVE, Toronto (CA); Raymond CHIK, Richmond Hill (CA); Lui Ray LAM, Lexington, MA (US)

(21) Appl. No.: 18/982,119

(22) Filed: Dec. 16, 2024

Related U.S. Application Data
(60) Provisional application No. 63/610,438, filed on Dec. 15, 2023.

(51) Int. Cl. G11C 11/412; G11C 11/418; G11C 11/419

(52) U.S. Cl. CPC G11C 11/412; G11C 11/418; G11C 11/419

(57) ABSTRACT

A low-power static random access memory (SRAM) for at-memory architecture is described. The SRAM in at-memory architecture is located adjacent to a Processing Element (PE) so that the same voltage is required at the SE and the SRAM connected to the PE. However, SRAM read/write operation needs different voltage than the PE. Accordingly, selective voltage supplies are described including adaptive voltage supplies (AVS). A bitline precharge level of 0.1V is described for ultra-low power. Moreover, to reduce the number of supply voltages, the bit cell voltage is set at standard cell voltage, Vddc for read, and at a PE operating voltage Vddp for a write.

### BACKGROUND OF THE INVENTION

### 1. Field of the Invention

The present invention is directed to static random access memory (SRAM), and more particularly to an on-chip SRAM that is located adjacent to a processing element (PE) of an at-memory compute architecture.

### 2. Description of the Related Art

There is a recognized need to reduce power dissipation in traditional SRAMs (e.g. Vdd supply voltage of 0.5 V or less), wherein a plurality of memory cells along a selected word-line are read or written via a bit line. Recently, this need has become more pressing with the introduction of emerging SRAMs used in artificial intelligence (AI) chips, wherein all of the memory cells are simultaneously read or written for massively parallel operations between processor element blocks and the SRAMs.

International patent application No. PCT/IB2022/055760 naming Sato, K et al., and entitled LOW-POWER STATIC RANDOM ACCESS MEMORY USING HALF VDD PRECHARGE, sets forth a method and apparatus for half-Vdd bit line precharge of six-transistor (6T SRAM) memory cells to reduce the bit line precharge power, compared to conventional prior art Vdd bit line precharge approaches. As disclosed in PCT/IB2022/055760, a 6T SRAM memory cell is arranged between a first bitline (BL), a second bitline (BLB) and a word line. A bitline precharge circuit precharges the first bitline and second bitline to a voltage of Vdd/2 prior to the 6T SRAM memory cell receiving a word line signal.

At-memory compute architectures have attracted attention in recent years (see Bob Beachler, “The Advantages of At-Memory Compute for AI Inference”, EETimes, Jan. 24, 2022). In contrast with the traditional von Neumann architecture having external DRAM, a cache, and a pipeline to access processing elements, an at-memory compute architecture has the processing elements (PEs) directly attached to the memory cells of a 6T SRAM to achieve high bandwidth interaction between processing element and SRAM. As the name implies, a key characteristic of the at-memory architecture is the physical connection between the processing elements “at the memory” that feeds them. Increasing demand for high TOPS/W for AI hardware acceleration requires compute hardware having high throughput under low power consumption (TOPS/W is a metric indicating how many computing operations an AI accelerator can handle in one second at 100% utilization). The processing element, which is the basic core unit of the compute hardware, needs to operate at lower voltages (e.g. 0.35˜0.4V) in order to reduce power. Hence, the operational voltage of the 6T SRAM, which is attached to the processing elements, is required to be reduced to the same voltage as that of the processing element. The power consumption of the bit line (BL) precharge circuit is a major contributor to the power consumption of the 6T SRAM.

Writing a voltage into the data line (din) of an SRAM 6T bit cell sets the bit cell to the that voltage. Generally speaking, reliability of SRAM read operations increases with a high bit cell voltage, and reliability of SRAM write operations increases with a low bit cell voltage. Moreover, in the case of low voltage operated processing elements, the data line voltage is set to the voltage domain of the processing element (e.g. 0.35˜0.4V). Conventional architectures therefore amplify the data line voltage to the same voltage as the bit cell voltage when writing into the data line.

### SUMMARY OF THE INVENTION

It is an aspect of the present invention to provide a low voltage and low power embedded SRAM system having high throughput for at-memory compute architecture Al chips where the SRAM is located on-chip adjacent to the processing element of the at-memory compute architecture. The SRAM therefore operates at two different low voltage domains, memory read/write voltage of 0.4V and a processing element coupled circuit voltage (vddp) of 0.35.

To minimize the number of supply voltages, the 6T bit cell voltage is set to the standard cell voltage (vddc), as provided by the foundry, to enhance bit cell store and read stability during read operations. During write operations, however, the 6T bit cell voltage is set to the processing element operating voltage (vddp, where vddp<<vddc), in order to enhance writability, so that the vddp level din/dinb can be input into the bit line directly without any amplification or level shifters. As discussed below, an exemplary cell vdd selector may be provided for setting the appropriate 6T bit cell voltage during read and write operations.

More particularly, according to an embodiment, the exemplary cell vdd selector sets the bit cell voltage to the processing element domain voltage during write operations, and to the same voltage as the highest voltage in the SRAM, such as the word line boost voltage (e.g. 0.75V), during read operations.

It is a further aspect of the present invention to provide an SRAM embedded in an Al chip that operates at low voltage and low power during read operations, which occur more often than write operations.

In another aspect, two different adaptive voltage supplies (AVS) are set forth to provide SRAM read/write operation voltages that are different than the processing element domain voltage to compensate for process and temperature variations. In an embodiment, a 0.1V bitline precharge level provides ultra-low power for SRAM read/write operations, which cannot be generated using DC-DC converters.

In a further aspect, a method and apparatus for charge sharing are set forth using segmented bit lines.

Additionally, a method and apparatus for seamless read operation is set forth without any segmented sub arrays.

If the processing element operates at 0.35V, it is preferred that the read word line voltage of SRAM is set at more than 0.35V, for example, 0.4V, at typical process or temperature conditions, because the read word line voltage of 0.35V will be too low to read out the differential signal from the SRAM bit cell. Moreover, the read word line voltage is required to be increased to more than 0.4V at slower process or low temperature conditions. This characterized voltage can be generated by an AVS, but in the case that 0.4V is required only for reading out the SRAM bit cell, the cost of an additional AVS is excessive. Therefore, a simple on-chip 0.4V generator is set forth herein that can handle process and temperature variations specially for operation of the SRAM.

In accordance with an aspect of an embodiment, there is provided a SRAM embedded in an at-memory architecture with a PE operating at a PE domain voltage vddp. The SRAM includes a bit cell and a cell vdd selector. The bit cell operates at a bit cell voltage vdd. The cell vdd selector generates the bit cell voltage at the PE domain voltage (vdd=vddp) during write operations and generates the bit cell voltage at a standard cell voltage (vdd=vddc) during read operations. The PE domain voltage is less than the standard cell voltage (vddp<<vddc).

In some embodiments, the SRAM further comprising a bit line (BL) precharge circuit for setting a bit line (BL) precharge voltage to less than half of the PE domain voltage (vddp/2) during read operations, and to half of the PE domain voltage (vddp/2) during write operations. The SRAM may include a negative Vss_cell generator having a charge pump circuit for pulling down a vss voltage of the bit cell to a negative voltage during read operations, and maintaining the vss voltage of the bit cell at 0V during write operations.

In some embodiments, the SRAM may include a read main amp (RMA) and latch disposed at every column on one side of processing element (PE), and data lines (din/dinb) input to the bit line (BL) from an opposite side of processing element (PE). The cell vdd selector may be disposed at every column at the opposite side of processing element (PE).

The bit line (BL) precharge circuit may include an isolation (ISO) switch for selectively partitioning the bit line (BL) for charge sharing between a far end segment and a near end segment of the bit line (BL) upon assertion of an ISO signal to generate the precharge voltage. The isolation (ISO) switch may be operable to adjust the bit line (BL) precharge voltage from half the PE domain voltage (vddp/2) during write operations to quarter the PE domain voltage (vddp/4) during read operations by twice short circuiting the two bit line (BL) portions via the isolation (ISO) switch for charge sharing.

In some embodiments, the SRAM may further include a word line (WL) driver for generating a two-step word line signal during write operations, wherein a first step is at a word line voltage of vddp, and a second step is at vddc, where vddc>vddp, and generating a single step word line signal at vddp during read operations. The word line (WL) driver may cause the word line signal to drop to 0V when data (Dout) on the word line (WL) is transferred to the latch. The bit line (BL) precharge circuit may start precharging the bit line (BL) for reading the data (Dout) on a next assertion of the word line signal.

In some embodiments, the voltage for the processing element (PE) may be generated by a first Adaptive Voltage Supply (AVS1) and the word line voltage for the word line (WL) driver may be generated by a second Adaptive Voltage Supply (AVS2).

In some embodiments, the SRAM further includes a plurality of process and temperature variation sensors (PT sensors) distributed in a chip incorporating the SRAM and processing element (PE). The output of each PT sensor may be applied to an analog-to-digital converter (ADC) whose output may be applied to control logic which selects a maximum voltage of the PT sensors for controlling a DC-DC converter to generate the word line voltage. The control logic may set a minimum voltage limit for the DC-DC converter.

In some embodiments, the SRAM further includes a cross-coupled NMOS located in the far end segment of the bit line partitioned by the isolation (ISO) switch from the read main amp (RMA) for discharging one of two bit line (BL) portions to ground during read operations. A source of the cross-coupled NMOS may be pulled down to a negative bias voltage for a period of time and thereafter returned to vss.

In some embodiments, each word line (WL) in the far end segment may have a different width than each word line (WL) in the near end segment. Each word line (WL) in the far-end segment may be turned-off after the isolation (ISO) switch partitions the bit lines (BL).

In some embodiments, the SRAM may include a top array and a bottom array, the top array and the bottom array controlled by independently assigned signals.

In some embodiments, the SRAM may further include a read main amp (RMA). An activation signal (RMA_EN) of the RMA may be activated earlier than a complementary activation signal (RMA_ENB) of the RMA. The activation signal (RMA_EN) may be activated and then the complementary activation signal (RMA_ENB) may be activated when a voltage difference between the bit line pair reaches a predefined voltage.

In some embodiments, the amplitude of the ISO signal for partitioning the bit lines (BL) may be from vddp-Vth to vddp during read, and Vddc may be fixed during write, being the second step word line voltage.

In some embodiments, the cell_vdd selector may perform a pseudo read via a masked write or no write operation in write mode such that a first portion of the WL signal is made the same voltage as during read operations.

In some embodiments, the standard cell voltage (vddc) may be generated by a series connection of two PE domain voltage (vddp) power sources.

These together with other aspects and advantages which will be subsequently apparent, reside in the details of construction and operation as more fully hereinafter described and claimed, reference being had to the accompanying drawings forming a part hereof, wherein like numerals refer to like parts throughout.

### BRIEF DESCRIPTION OF THE DRAWINGS

FIG. 1 shows a SRAM cell array according to the prior art.

FIG. 2 shows a 6T SRAM cell array, according to an embodiment.

FIG. 3A is a simplified representation of a Cell Vdd selector of the 6T SRAM shown in FIG. 2, according to an embodiment.

FIG. 3B is a cel_vdd waveform produced by the Cell Vdd selector shown in FIG. 2, according to an embodiment.

FIGS. 3C and 3D are input and output data line waveforms, respectively, of voltages on bit cell data lines of the 6T SRAM shown in FIG. 2, according to an embodiment.

FIG. 3E shows an example of details of a Cell Vdd selector of the 6T SRAM shown in FIG. 2, according to an alternative embodiment.

FIG. 3F is a timing diagram for operation of the Cell Vdd selector shown in FIG. 3E, according to an embodiment.

FIG. 3G shows details of another example of a Cell Vdd Selector and 4:1 multiplexer, according to an embodiment of the 6T SRAM shown in FIG. 2.

FIG. 3H shows an array of 6T SRAM bit cells shown in FIG. 2, read main amplifiers (RMAs), latches and a 4:1 multiplexer, according to an embodiment.

FIG. 3I shows series connection of 6T SRAM bit cells, read main amplifiers (RMAs), latches and 4:1 multiplexers of FIG. 3H to increase array density with a doubling of the number of rows while retaining the same number of columns.

FIG. 3J shows a cross-coupled NMOS circuit (CP_NMOS), according to an embodiment of the 6T SRAM bit cell shown in FIG. 3H or FIG. 3I.

FIG. 3K shows an embodiment of the read main amplifier, shown in FIG. 3H or FIG. 3I.

FIG. 3L shows an embodiment of the read main amplifier, shown in FIG. 3H or FIG. 3I, according to an alternative embodiment.

FIG. 4 is a timing diagram showing operation of the 6T SRAM shown in FIG. 2

FIG. 5 shows dependency of bit line precharge power on precharge level (voltage).

FIG. 6A shows a bit line charge sharing circuit to generate a low BL precharge level, according to an embodiment.

FIG. 6B is a simplified timing diagram showing operation of the bit line charge sharing circuit of FIG. 6A.

FIG. 6C is a simplified timing diagram similar to FIG. 6B showing word line transitions during operation of the bit line charge sharing circuit of FIG. 6A.

FIGS. 6D and 6E are detailed timing diagrams showing operation of the charge sharing circuit of FIG. 6A for adjusting the bit line (BL) precharge level from write to read operations.

FIG. 6F is a simplified timing diagram showing operation of the cross-coupled NMOS circuit shown in FIG. 3F within the charge sharing circuit of FIG. 6A.

FIG. 6G shows a cross-coupled NMOS circuit (CP_NMOS), according to further embodiment of the 6T SRAM bit cell shown in FIG. 3F.

FIG. 6H is a simplified timing diagram showing operation of the cross-coupled NMOS circuit of FIG. 6G.

FIG. 7A shows a negative Vss_cell generator according to an embodiment. FIG. 7B is a timing diagram of the Vss_cell generator of FIG. 7A.

FIG. 8A shows a 6T SRAM cell array, according to an embodiment wherein a latch is placed in each column.

FIG. 8B is a timing diagram showing operation of the 6T SRAM cell array of FIG. 8A.

FIG. 9A and FIG. 9B are simplified circuit diagrams showing adaptive voltage supplies AVS1 and AVS2, respectively, for powering the 6T SRAM and PE, where the output voltage V_AVS2 is equal or greater than output voltage V_AVS1.

FIG. 10 shows a plurality of process and temperature (PT) sensors associated with the adaptive voltage supplies AVS1 and AVS2, distributed in a chip.

FIG. 11A and FIG. 11B illustrate circuitry for connecting multiple PT sensors to the first adaptive voltage supply circuit of FIG. 9A and the second adaptive voltage supply circuit of FIG. 9B, respectively.

FIG. 12 shows a flash type Analog-to-Digital Converter (ADC) with an encoder for deriving an adaptive voltage from the outputs of the PT sensors.

FIG. 13A and FIG. 13B show internal logic of the encoder for deriving the adaptive voltage.

FIG. 14 shows additional internal logic of the encoder for ensuring that the derived adaptive voltage exceeds the minimum value for SRAM operation.

FIG. 15A shows an on-chip 0.4V generator with process and temperature compensation bias circuit.

FIG. 15B shows process and temperature dependency of the on-chip voltage generator of FIG. 15A.

FIG. 16 shows a series connection of two vddp supply sources to generate vddc, in order to minimize the number of supply sources, according to an embodiment.

### DETAILED DESCRIPTION OF THE PREFERRED EMBODIMENTS

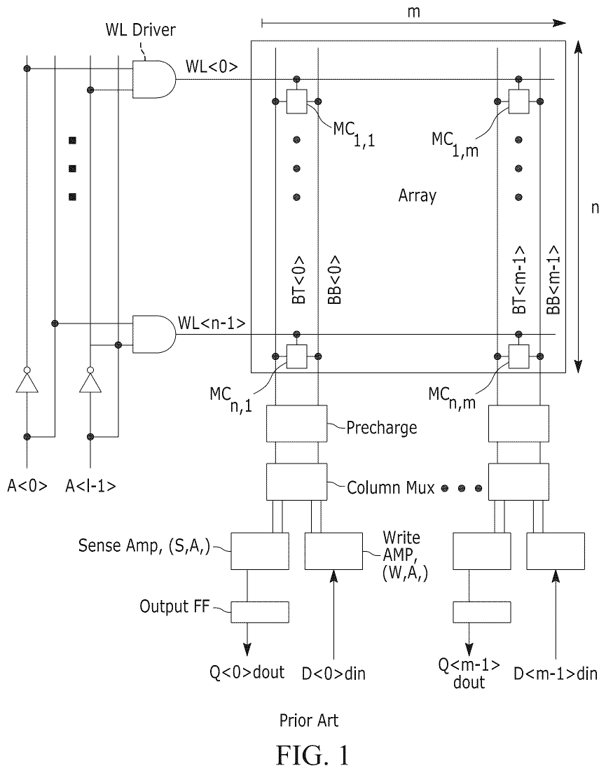

A conventional SRAM cell array is shown in FIG. 1, comprising a plurality of SRAM cells MC_{1,1} . . . MC_{1,m} . . . MC_{n,1} . . . MC_{n,m}, to which binary data (dout, din) is read/written on bit lines BT<0>/BB<0> . . . . BT<m−1>/BB<m−1>via column precharge, multiplexers (column mux), and sense/write amplifiers ((S.A.) and W.A., respectively), in response to read/write signals applied to word lines WL<0> . . . . WL<n−1>by a word line (WL) driver.

As discussed above, PCT/IB2022/055760 sets forth a method and apparatus for half-Vdd bit line precharge in 6T SRAM memory cells to reduce the bit line precharge power, compared with conventional Vdd bit line precharge schemes. In operation, the method and apparatus of PCT/IB2022/055760 provides one half bit line-power during read and write operations with halved bit line-swing. According to an additional aspect of PCT/IB2022/055760, a further low power configuration is provided for reducing the bit line high voltage level from Vdd to a reduced voltage (Vddr) by means of a Vddr generator. A major advantage of the half-Vdd bit line precharge scheme of PCT/IB2022/055760 is very easy generation of the half-Vdd voltage level by shorting bit lines BL and BLB.

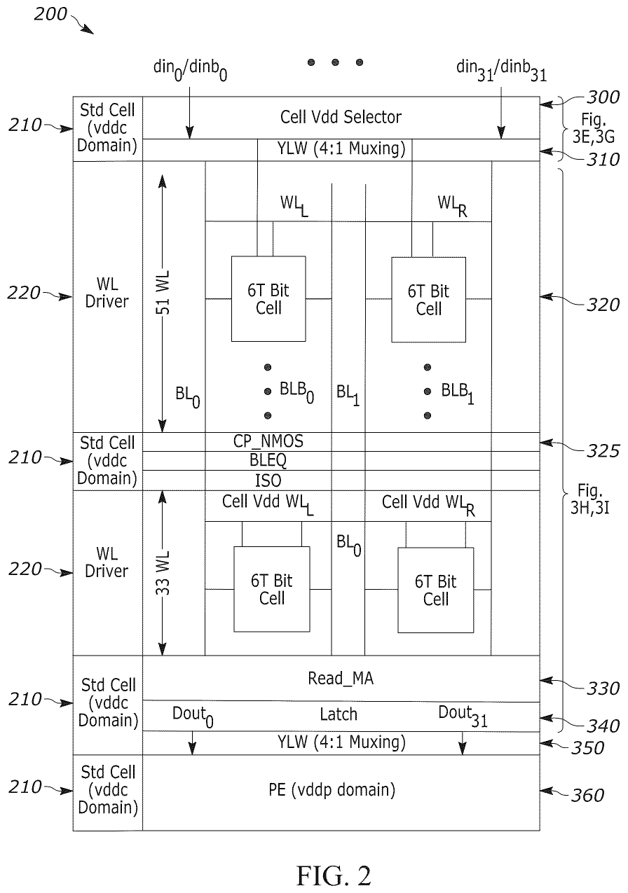

FIG. 2 shows an array 200 of 6T SRAMs embedded in an at-memory architecture, and connected to I/O peripheral circuits 210 in the form of standard cells operating in the standard memory voltage domain, and word line (WL) drivers 220 for driving Word Lines (WLL and WLR) according to an embodiment. The array 200 comprises a Cell Vdd selector 300, input 4:1 multiplexer 310, plurality of 6T Bit Cells 320, cross-coupled NMOS circuit (CP_NMOS) 325, read main amplifier (RMA) 330, latch 340 and output 4:1 multiplexer 350 connected to a Processing Element (PE) 360 of the at-memory compute architecture. Additional details of 6T Bit Cell 320, cross-coupled NMOS circuit (CP_NMOS) 325, read main amplifier 330, latch 340 and output 4:1 multiplexer 350 are discussed below.

In order to minimize capacitance on the bit lines (BLs) and reduce power during read operations, which occur more often than write operations in AI chips, the read path of the bit lines connect to read main amplifier 330 which is connected directly to processing elements 360 resulting in a simple, short bit line path with minimal additional capacitance.

The 6T bit cell 320, read main amplifier 330, latch 340, output 4:1 multiplexer 350 operate in the standard memory R/W voltage domain with a bit cell voltage (vddc), for example 0.4V, and processing elements 360 operate in a processing element voltage domain (vddp), for example 0.35V, for 7 nm or 5 nm Fin Field-Effect Transistor (FinFET) technology.

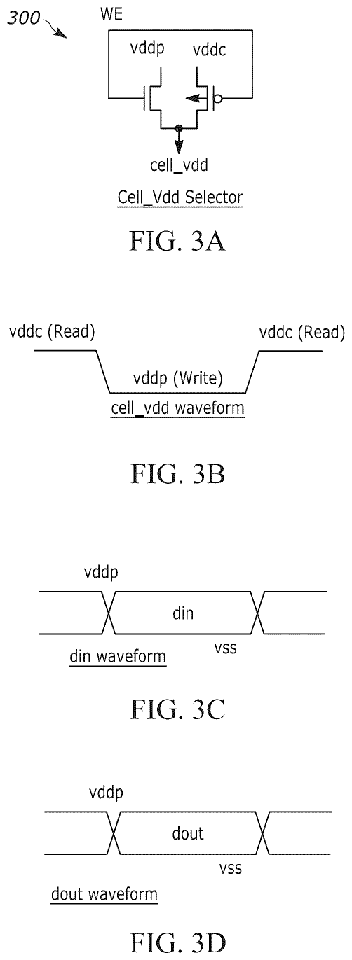

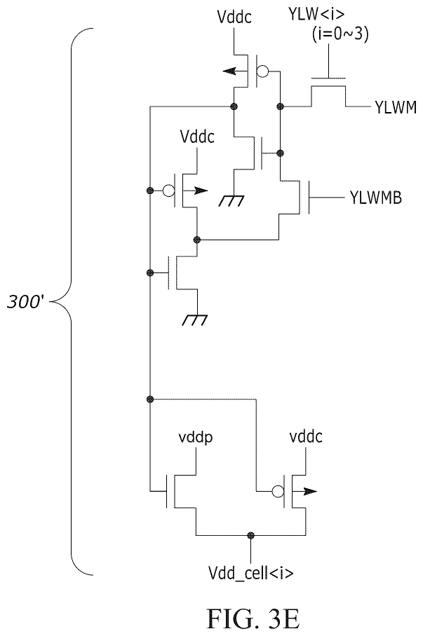

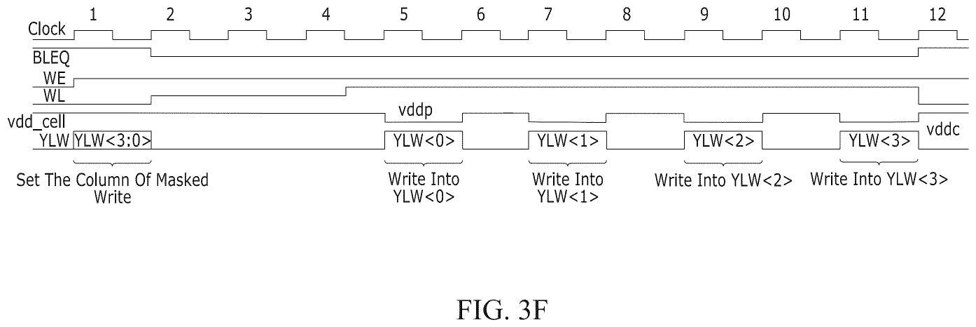

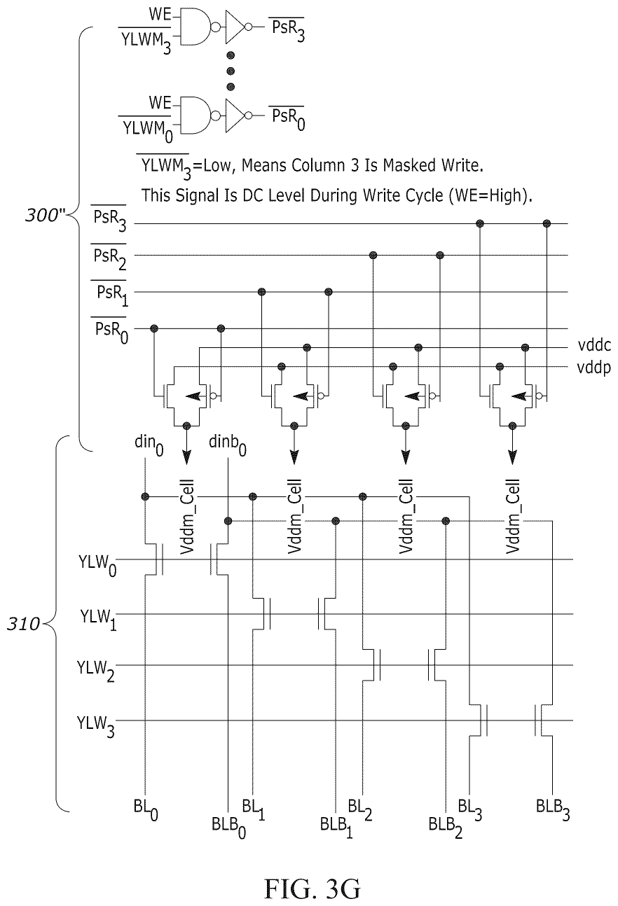

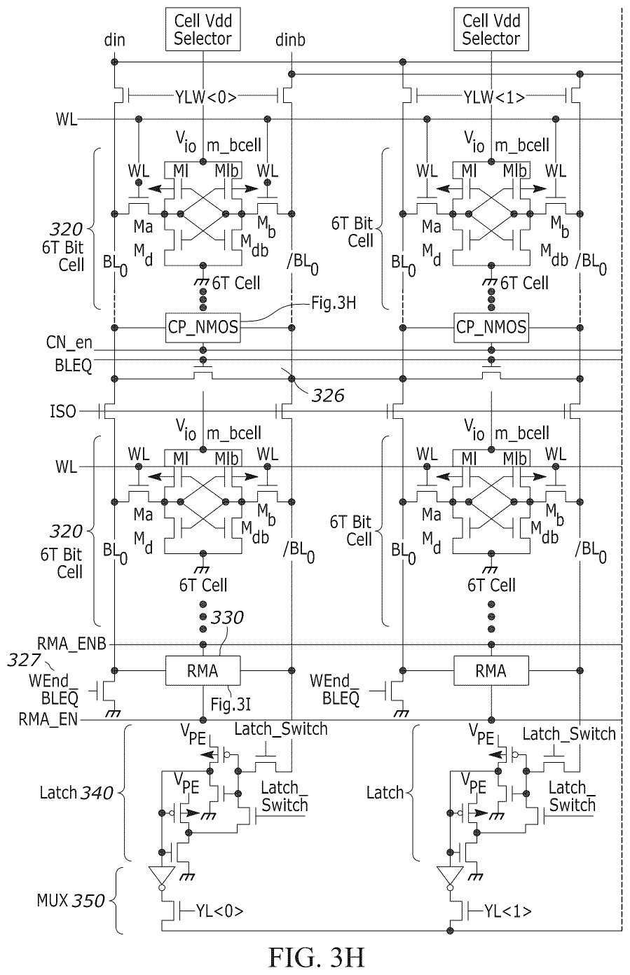

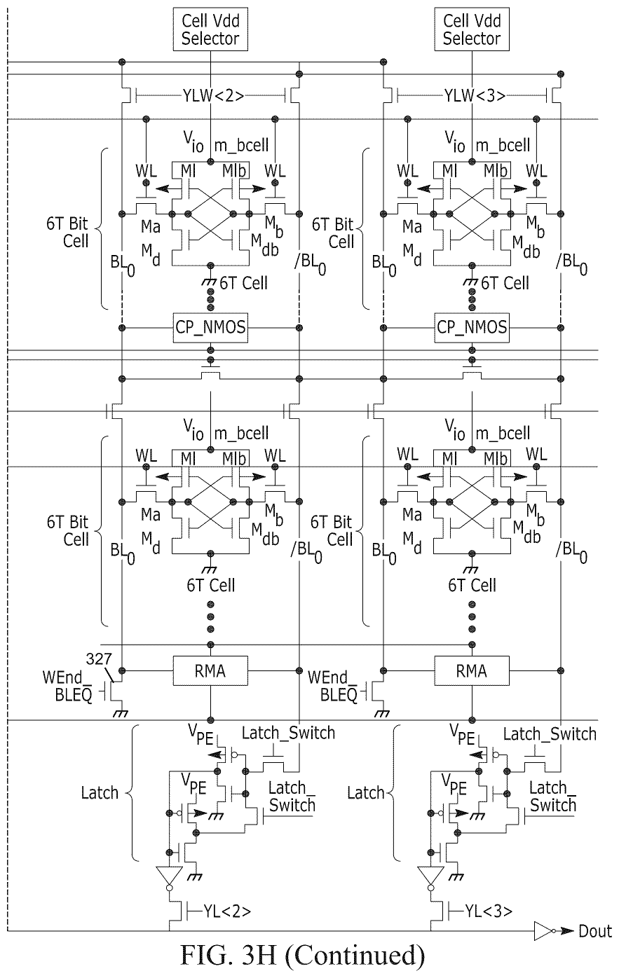

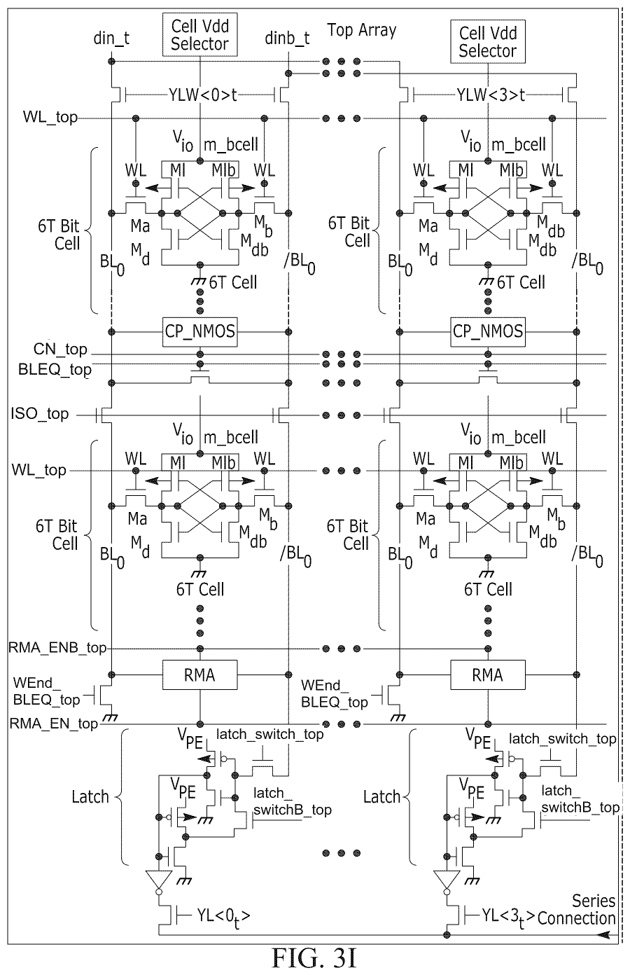

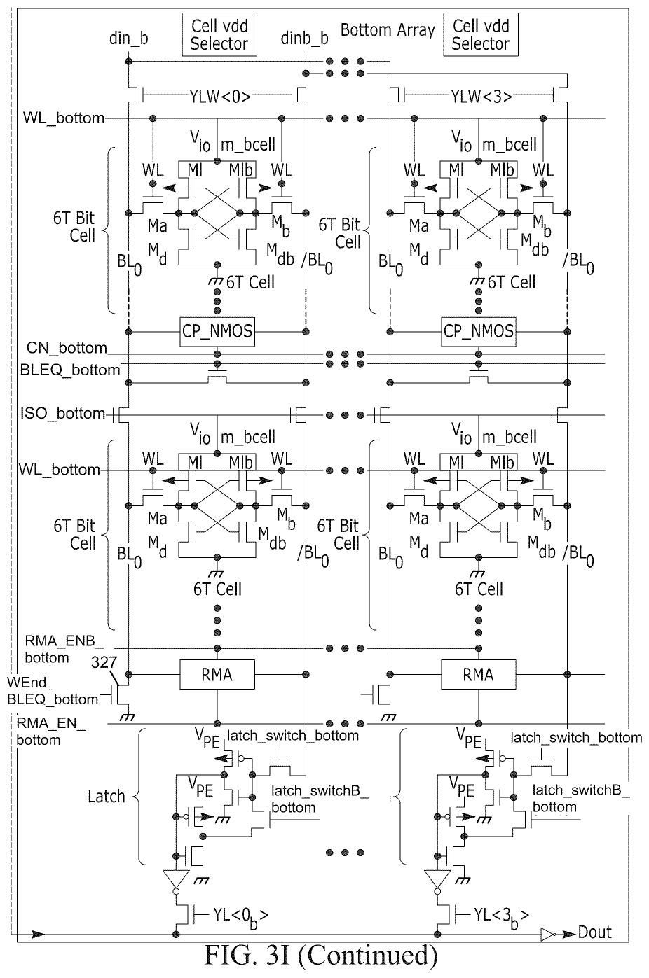

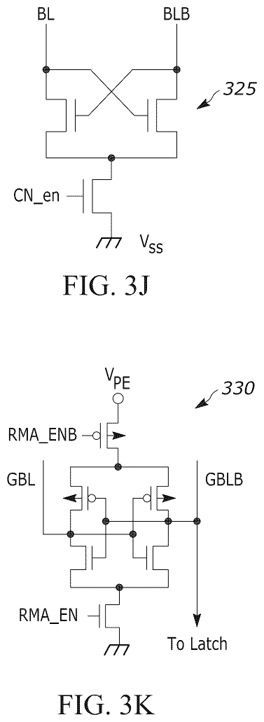

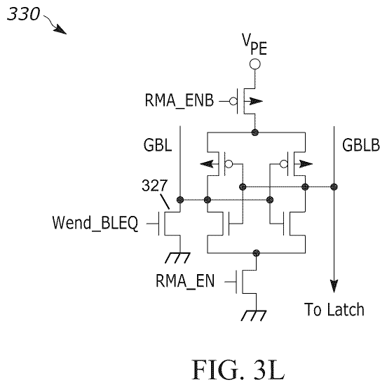

Therefore, according to an embodiment, a Cell Vdd selector 300 is shown in simplified form in FIG. 3A. The illustrated Cell Vdd selector 300 sets the bit cell voltage (cell_vdd) to the processing element domain voltage (vddp=0.35V) during write operations. In the illustrated Cell Vdd selector 300, this occurs when the Write Enable (WE) signal is high. Conversely, the illustrated Cell Vdd selector 300 sets the bit cell voltage (cell_vdd) to the standard cell voltage (vddc=0.75V) during read operations. In the illustrated Cell Vdd selector 300, this occurs when the Write Enable (WE) signal is low. An example timing diagram illustrating change of the bit cell voltage (cell_vdd) output from Cell Vdd selector 300 is shown in FIG. 3B. Example timing diagrams illustrating that data lines din and dout are swung from vss (0V source voltage) to the processing element domain voltage (vddp) during write and read operations, respectively, as shown in FIG. 3C and 3D. In some embodiments, the bit cell voltage (cell_vdd) may be set to the same voltage as the highest voltage in the SRAM, such as word line boost voltage (e.g. 0.75V), during read operations, as discussed below.

Another example of the Cell Vdd Selector 300′ is shown in FIG. 3E. In this example, the Cell Vdd Selector 300′ holds the column data of masked write, given at the beginning of the write, by a latch circuit. Referring to FIG. 3F, a timing diagram for operation of the Cell Vdd selector shown in FIG. 3E according to an embodiment is shown. The

[symbol]

FIG. 3G shows details of another example of the Cell Vdd Selector 300″. In this example, the Cell Vdd Selector 300″, comprises a plurality of logic gates configured to logically combine the WE signal with each of the masked write signals YLWM₀ to YLWM₃. The logic gates are configured to output column write enable signals P̅s̅R̅₀̅ to P̅s̅R̅₃̅ for respective ones of the masked write signals YLWM₀ to YLWM₃. The column write enable signals P̅s̅R̅₀̅ to P̅s̅R̅₃̅ are high when both the WE signal indicates a write operation and the corresponding masked write signals YLWM₀ to YLWM₃ indicates that the specific column is not masked. Thus, the Cell Vdd Selector 300″ changes the bit cell voltage (cell_vdd) for a particular column upon enabling the WE sign only if the column is not masked.

FIG. 3H shows details of an array of 6T SRAM bit cells 320 shown in FIG. 2, read main amplifiers 330, latches 340 and a 4:1 multiplexer 350, according to an embodiment. For an array of 80 rows×128 columns, there are 32 data outputs (Dout₀ . . . Dout₃₁, as shown in FIG. 2) because of the 4:1 multiplexor 350 and four PEs with x8 I/O, such that each PE has 320B (=80×128/4/8).

In order to double the PE density of 320B to 640B/PE, a simple series connection 353 of arrays can be provided, as shown in FIG. 3I, where the pre-stage node of the Dout inverter allows for a simple wired-or connection. The example illustrated in FIG. 3I, comprises a top array and a bottom array. In this example, the signals for the top array and the signal for the bottom array are independently assigned. Thus, the top array and the bottom array can be operated independently. This allows a simultaneous burst write in the top array and burst read in the bottom array, for example. Similarly, a simultaneous burst read can be performed in the top array and burst write in the bottom array.

FIG. 3J shows details of cross-coupled NMOS circuit 325, according to an embodiment of the 6T SRAM bit cell shown in FIG. 3H or FIG. 3I.

FIG. 3K and 3L shows details of embodiments of the read main amplifier 330, shown in FIG. 3H or FIG. 3I. The read main amplifier 330 is enabled by activation signals RMA_EN and RMA_ENB. In some embodiments, when the activation signals RMA_EN and RMA_ENB are activated simultaneously, there is potential that a crowbar current will flow, which is undesirable from a power consumption point of view. Accordingly, to address this issue, the activation signal RMA_EN is activated earlier than the complementary activation signal RMA_ENB. For example, the complementary activation signal RMA_ENB can be delayed from the activation signal RMA_EN by a half or whole cycle. In some embodiments, the complementary activation signal RMA_ENB is delayed until the voltage difference between the bit lines, BL and BLB, reaches a predefined voltage. In some embodiments, the predefined voltage difference is about 100 mV.

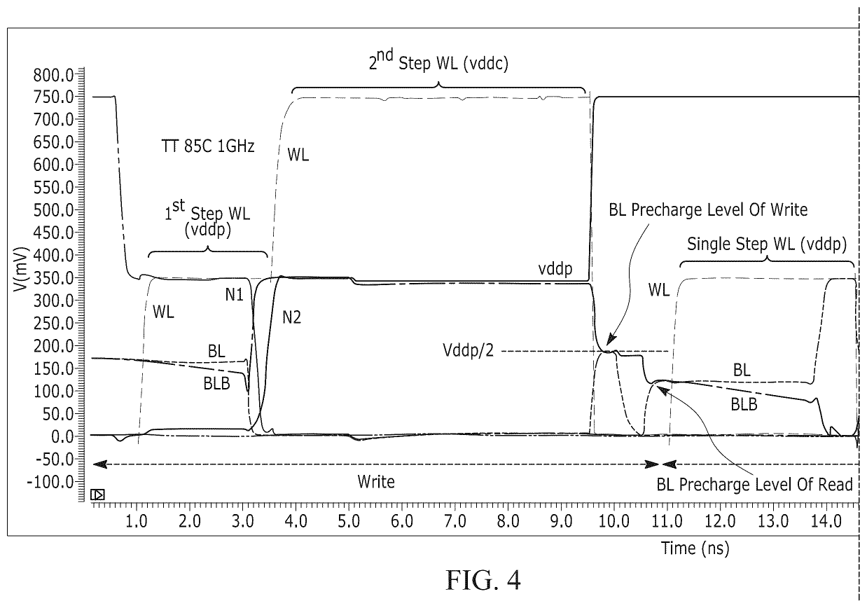

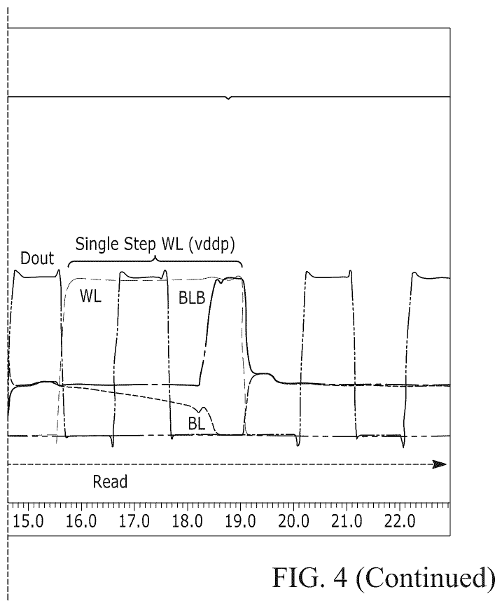

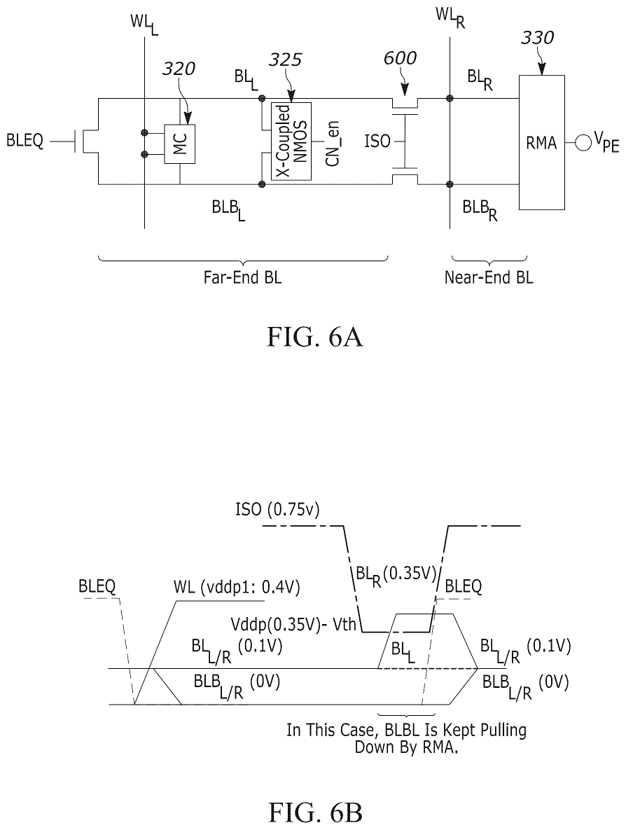

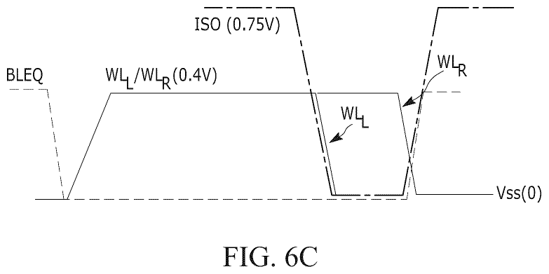

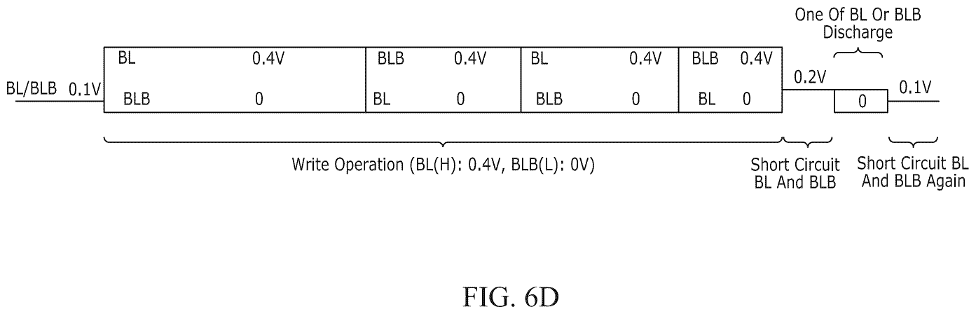

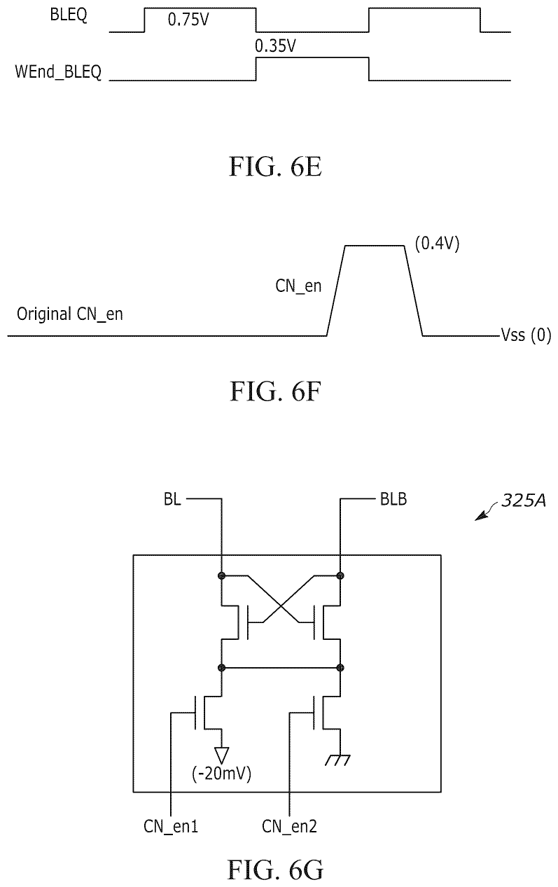

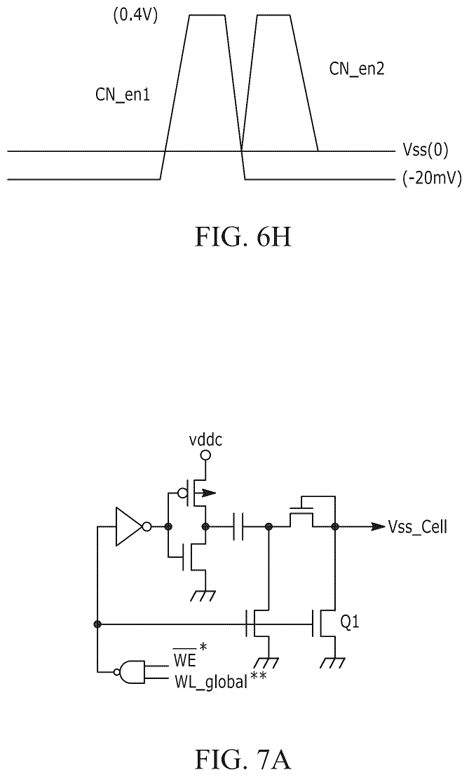

FIG. 4 shows operation of the 6T SRAM shown in FIG. 2, wherein Cell Vdd selector 300 sets the bit cell voltage (cell_vdd) to the processing element domain voltage (N2=vddp=0.35V) during write operations, and to the word line boost voltage (0.75V), during read operations, and wherein the bit line precharge voltage is set to less than half of vddp during read operations, and to vddp/2 during write operations, by a method of charge sharing using a partitioned bit line, as discussed in greater detail below with reference to FIGS. 6A and 6B.

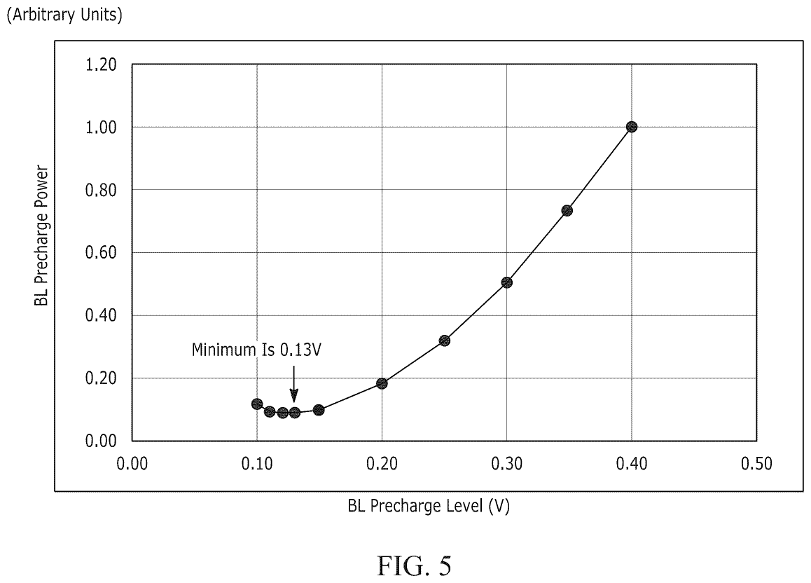

FIG. 5 shows the dependency of bit line precharge power on precharge level (voltage), from which it will be seen that a 0.13V (˜0.1V) precharge level provides minimum power consumption. To set the bit line precharge level to 0.1V with low power consumption for a processing element domain voltage of, for example, 0.35V, a charge sharing scheme is provided wherein, according to an embodiment, the bit line is partitioned into two portions BL_{L}, BLB_{L} and BL_{R}, BLB_{R} by an isolation (ISO) switch 600, as shown in FIG. 6A. During bit line precharging, the two bit line portions are connected by closing the ISO switch 600. Once the read out operation starts and the read signal reaches about 100 mV, the two bit line portions are separated by opening ISO switch 600, and the shorter bit line portion BL_{R}, BLB_{R} adjacent to the read main amp 350, is amplified rail-to-rail, for example, from vss to vddp (0.35V), as shown in FIG. 6B. After the read out operation, the two portions of the bit line are connected by closing ISO switch 600, such that charge sharing occurs from the shorter bit line portion BL_{R}, BLB_{R}, amplified to vddp, to the longer portion BL_{L}, BLB_{L}, which stays at a level lower than vddp, to generate the 0.1V bit line precharge level. Thus, the purpose of closing ISO switch 600 is to separate the two portions of the bit line when the shorter portion adjacent to RMA 330 is amplified to the PE domain voltage (vddp), which is not required to be at the vss level of the ISO switch 600. However, it is required to be at most at the threshold voltage of the ISO switch 600 (vddp-vth) to avoid amplified PE domain voltage (vddp) level degradation. Setting the ISO switch 600 to the low level of the threshold voltage (vddp-vth) results in the RMA 330 pulling down the voltage of the long portion of the bit line.

As shown in FIG. 6C, the “far end” word lines WL_{L} (i.e. on the far-end of the bit line segmented by the ISO switch 600 from RMA 330) turns off just after ISO switch 600 separates the two segmented bit lines in order to reduce the bit cell currents induced by the high state of the far-end segmented bit line, for example, 0.1V. The width of the word lines WL_{R} on the “near-end” of the segmented bit lines turns off just before bit line precharge starts as a result of assertion of the BLEQ signal, as shown in FIG. 6C.

In an embodiment, the bit line partition ratio can be calculated as follows: if the bit line capacitance is 10 fF and the capacitance of the read main amplifier 330 is 0.2 fF, from the law of conservation of charge, C(BL_{L})×0.1 +(C(BL_{R})+0.2)×0.4=2 C(BL_{L})×0.1+2 (C(BL_{R})+0.2)×0.1. To solve this equation using C(BL_{L})+C(BL_{R})=10 fF, the capacitance partitioning of BL should be C(BL_{L})=6.8 fF and C(BL_{R})=3.2 fF.

During write operations, BL and BLB are floating by opening the BLEQ short NMOS 326 and applying a write voltage (e.g. voltage step from vss=0V to vddp=0.4V). Then, after the write operation, BLEQ NMOS 326 short circuits BL and BLB such that the BL precharge level becomes vddp/2. In order to adjust the BL precharge level from write to read, the BL that is precharged at vddp/2 after write is discharged to vss by Wend BLEQ NMOS 327, and then BLEQ NMOS 326 short circuits bit lines BL and BLB again such that the new BL precharge level becomes half of vddp/2, or vddp/4. Thus, for the example of vddp=0.4V, then vddp/4=0.1V, which is the read BL precharge level. On the other hand, for the example of vddp=0.35V, the BL precharge level during write becomes vddp/2=0.175V and the BL precharge level during read becomes vddp/4=0.085V. In this case, the number of turn-ons of Wend BLEQ NMOS 327 in FIG. 3H and 3I can be adjusted less than the all Wend BLEQ NMOS number to generate 0.1V after short circuiting the bit lines GBL/GBLB. In summary, according to embodiments, the BL precharge level can be 0.1V during read operations and vddp/2 during write operations by short circuiting BL and BLB twice using BLEQ NMOS 326 to adjust the two different BL precharge levels. Timing diagrams for operation of BLEQ NMOS 326 and Wend_BLEQ NMOS 327 to achieve the required precharge BL levels during write and read operations, are shown in FIGS. 6D and 6E.

In the case that WLR is selected and the operating conditions are at the slowest process corners and/or at temperatures where transistors are the slowest etc., BLB_{L} will not be pulled down to Vss completely, through the bit-cell access transistors controlled by WL_{R}, before the ISO switch 600 is opened (assuming the data value is such that BL=High and BLB=Low). In order to obtain a Vpre_read=0.1V BL precharge level through charge sharing, the voltage of BLBL needs to be pulled down to Vss. Therefore, as shown in FIG. 6A, cross-coupled NMOS circuit 325 can be provided, as shown in FIG. 3H, between BL_{L} and BLB_{L}. The cross-coupled NMOS circuit 325 pulls down the voltage of BLBL to Vss without requiring assistance of the bit-cell selected by WL_{R}.

In the event that the threshold voltage of the cross-coupled NMOS circuit 325 of FIG. 3H becomes too high to discharge BL due to process variation etc., the source of the cross-coupled NMOS circuit, which is set to Vss, can be pulled down to a negative bias for a period of time (e.g., one half cycle), and then returned to Vss. Therefore, an alternative embodiment of cross-coupled NMOS circuit 325A can be provided, as shown in FIG. 6G where the source can be pulled down to −20 mV by a control signal CN_en1, as shown in FIG. 6H.

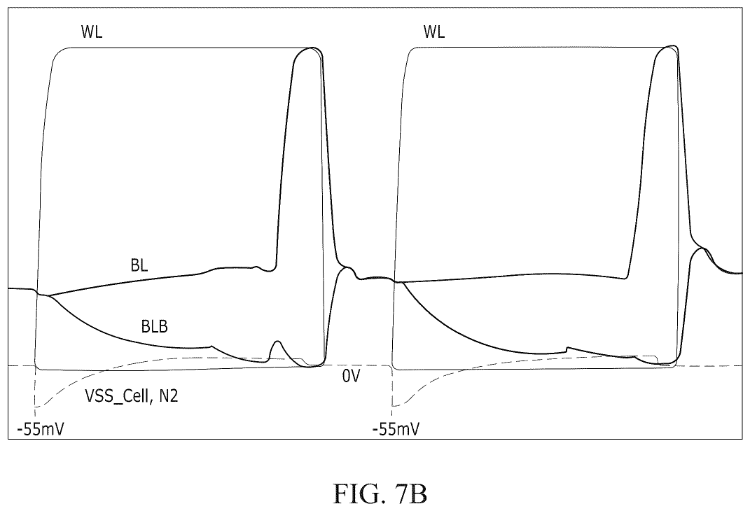

When the bit line precharge level is at a low voltage, such as 0.1V, and the word line read voltage from the WL driver 220 is 0.4V, the high store node of the 6T SRAM bit cell 320 cannot significantly pull the voltage of one of the bit lines BL up from 0.1V. On the other hand, the low store node of 6T SRAM bit cell 320 tries to pull down the other BL toward vss. Accordingly, a negative Vss_cell generator 700 can be provided, as shown in FIG. 7A for pulling down vss to a negative voltage, such as −55 mV, which allows the BL voltage to be pulled down, resulting in strong tolerance to variations in bit cell transistor conductance. During write operations,/WE is low such that Vss=0 due to transistor Q1. In contrast, during read operations/WE is high, so each time the WL_global signal is asserted charge pump produces a negative Vss_cell voltage, as shown in FIG. 7B.

The word line (WL) voltage impacts the bit cell data hold margin during read operations, and the write margin during write operations. In order to enhance the write margin, a higher word line voltage is preferred during write operations, and a lower word line voltage is preferred to enhance the bit cell data hold margin during read operations, although if the word line voltage is too low data cannot be read out from the bit cell 320. According to an embodiment, a two-step word line (WL) signal is generated by the word line driver 220 having a lower WL voltage (e.g. 0.4V) during read operations, and during write operations a first portion of the WL signal is made the same voltage as during read operations by performing a “pseudo read” via a masked write or no write operation in write mode, and thereafter the WL signal is boosted to a higher voltage to enhance writability. In the event of a masked write, the bit cell vdd of the masked write column remains at the same voltage as that during read operations. For example, the first step of the two-step WL signal during write operations can be at vddp while the second step can be at vddc, whereas the WL signal can be at vddp during read operations, as shown in FIG. 4. The WL signal drops to 0V when data (Dout) on the word line (WL) is transferred to latch 340, and BL precharging then commences for reading the data on the next assertion of the WL signal.

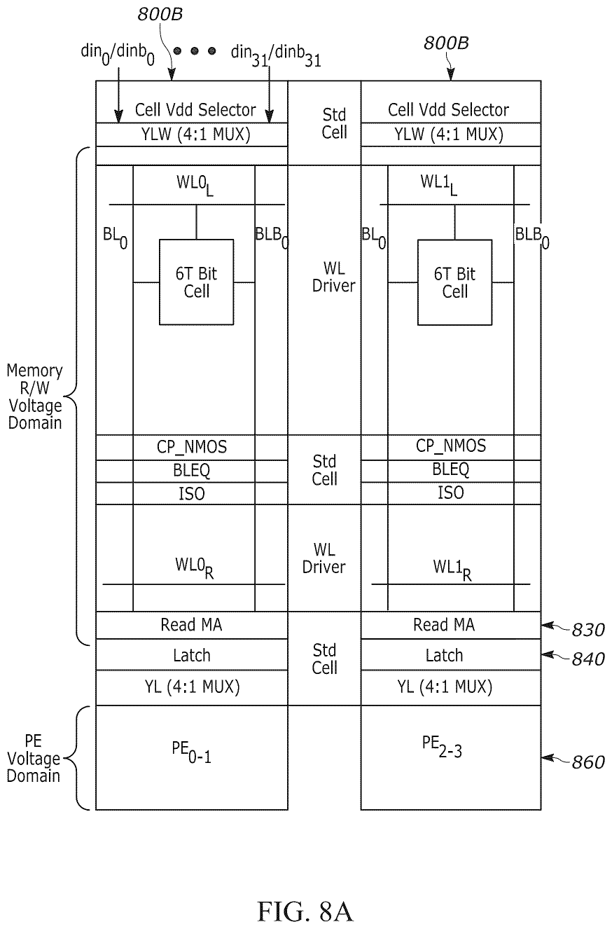

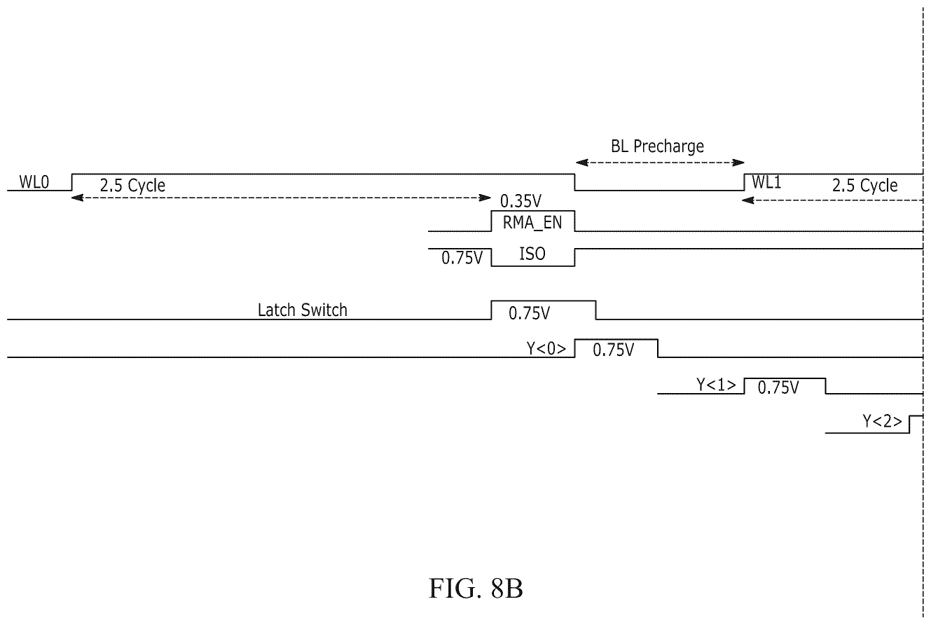

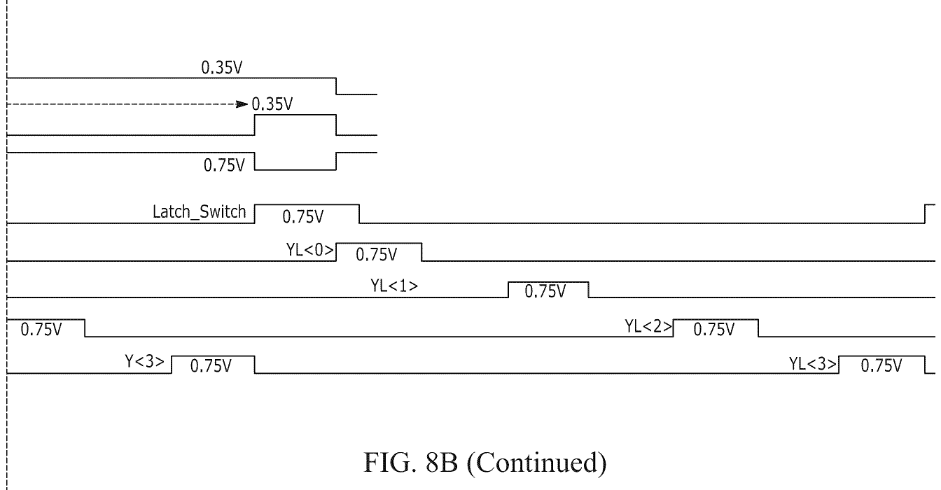

Ping-pong operation between two separate sub-arrays realizes seamless read, conventionally, but adds to cost in terms of additional layout area between two subarrays and to complexity in terms of timing. On the other hand, one large array, such as shown in FIG. 2, is simple and effective from a circuit design and layout area viewpoint, provided seamless read can be achieved without ping-pong operation. In accordance with an embodiment, as shown in FIG. 8A, a common word line driver is located between sub-arrays 800A and 800B, which are provided with a latch 840 in the column of each array. After all bits on a word line (WL) in sub-array 800A are amplified by the read main amp (Read MA 830) and its output is transferred to the latch 840, the word line can be turned off and the other word line in sub-array 800B can be turned on to amplify the data by read main amp 830, while the latch 840 in sub-array 800A is outputting the data to the processing element 860. Seamless read operations are therefore possible in this way, without ping-pong operation between two different subarrays, as shown in the timing diagram of FIG. 8B, where the word line (WL) signal drops to 0V when data (Dout) on the word line is transferred to the latch 840, and bit line precharging commences for reading the data on the next assertion of the word line signal.

In semiconductor manufacturing, process corners represent the extremes of fabrication parameter variations within which a circuit that has been etched onto a wafer must function correctly. One naming convention for process corners is to use two-letter designators, where the first letter refers to the N-channel (NMOS) corner, and the second letter refers to the P-channel (PMOS) corner. In this naming convention, three corners exist: typical, fast and slow. Fast and slow corners exhibit carrier mobilities that are higher and lower than normal, respectively. For example, a corner designated as FS denotes fast N-channel and slow P-channel. There are five possible corners: typical-typical (TT) (i.e. typical in terms of n vs. p mobility), fast-fast (FF), slow-slow (SS), fast-slow (FS), and slow-fast (SF). The TT, FF and SS corners are called even corners, because both types of devices are affected evenly, and generally do not adversely affect the logical correctness of the circuit.

The split between bit line signal BL and BLB shown in FIG. 4 depends on the process corner and temperature for a read operation. Although the PEs can work at low voltages, such as 0.35V, at nominal conditions such as TT corner and 85 C, as shown in FIG. 4, such low voltages are not high enough for the SRAM SA (sense amplifier) or the PE to operate successfully at the slowest process corner and/or the lowest temperature (SS corner and −40 C) unless the word line voltage is increased.

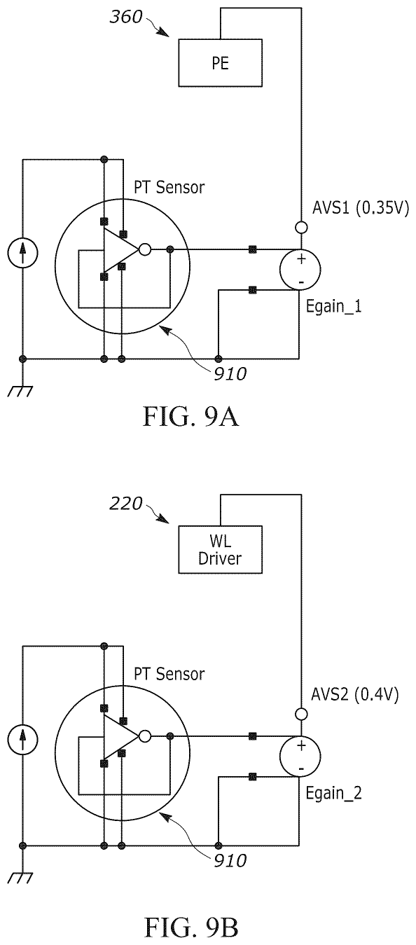

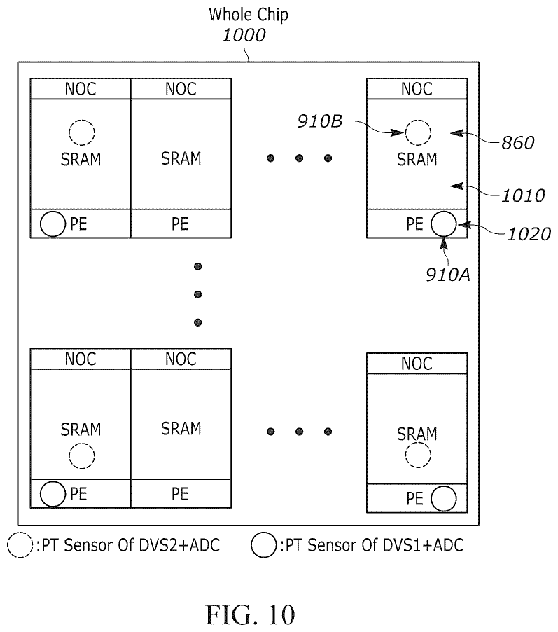

As discussed above, according to aspects of this specification, a method and apparatus are set forth for operating a 6T SRAM under two different low voltage domains (e.g. a memory read/write voltage of 0.4V and a PE coupled circuit voltage of 0.35V, for 7 nm or 5 nm FinFET technology), or a low voltage domain by matching the higher voltage to the lower voltage, where two different voltages are set to the same voltage, 0.35V, in at-memory compute architecture AI chips. Therefore, as shown in FIG. 9A and 9B, adaptive voltage supplies AVS1 and AVS2 are provided having DC-DC converters 900 for powering the 6T SRAM and PE, where the output voltage V_AVS2 is equal or greater than output voltage V_AVS1. In an embodiment, Egain_1 of the DC-DC converter of FIG. 9A generates 0.35V, and Egain_2 of the DC-DC converter of FIG. 9B generates 0.4V. The 1^{st} AVS, which generates V_AVS1, is applied to the voltages of PE, MA, bit line data latch, column select signal, and Dout. The 2^{nd} AVS, which generates V_AVS2, is applied to the voltages of the read word line. The DC-DC converters are supplied by an adaptive voltage output from an ADC (Analog Digital Converter) whose inputs come from process and temperature (PT) sensors 910A and 910B that are distributed in a chip 1000, as shown in FIG. 10. The PT sensor 910B associated with AVS2 of FIG. 9B is placed in the SRAM area 1010, while the PT sensor 910A associated with AVS1 of FIG. 9A is placed in the PE area 1020.

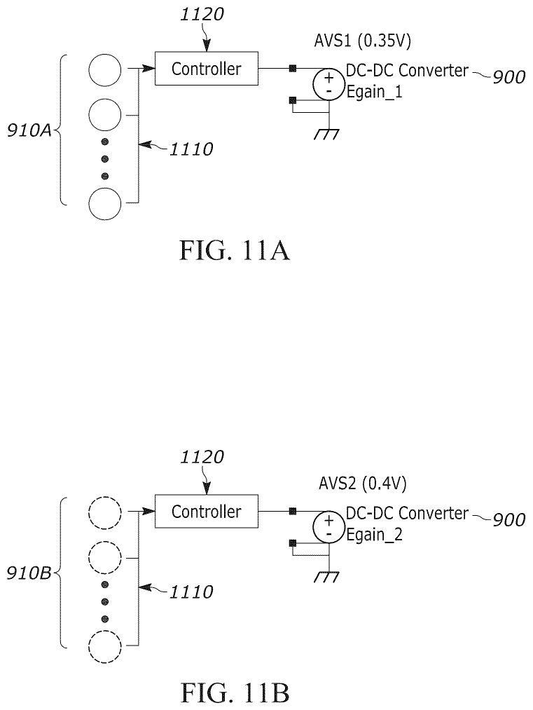

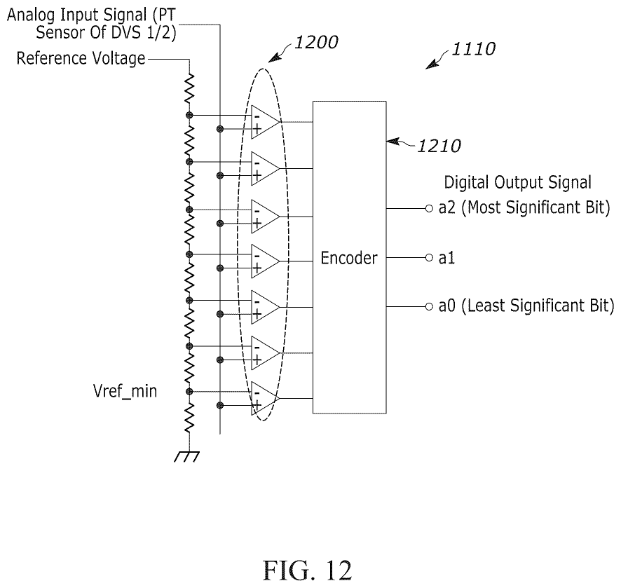

FIG. 11A and FIG. 11B illustrate the circuit organization of PT sensors 910A, 910B, Analog-to Digital Converter (ADC) 1110, logic controller 1120 and DC-DC converter 1130 for the first adaptive voltage supply circuit of FIG. 9A and the second adaptive voltage supply circuit of FIG. 9B, respectively. The output of each PT sensor 910A and 910B is passed to the ADC 1110, whose output feeds the DC-DC converter 1130 through the logic controller 1120. The logic controller 1120 takes an adaptive voltage value, which is the maximum or average, from the plural PT sensors 910A and 910B distributed as shown in FIG. 10. In response, the logic controller 1120 sets the minimum voltage, as described below. The output of the logic controller 1120 is then sent to the DC-DC 1130 converter to secure operation margin.

FIG. 12 shows an exemplary flash type ADC 1110 comprising a plurality of comparators 1200 whose outputs are connected to inputs of an encoder 1210. The analog voltage signal from the associated PT sensor 910A, 910B is applied to the first inputs of the comparators and a reference voltage signal Vref_min is applied to the second inputs, resulting in a 3-bit digital signal: a0, a1, a2 at the output of the encoder. For a range of analog input signals from the PT sensor of 300 mV to 450 mV, for example, Vref_min can be set to 330 mV, resulting in a minimum voltage code.

Each PT sensor 910A, 910B outputs a different value depending on the localized PT variation. When the adaptive voltage output is high, the power consumption will be increased, providing good operation margin. Therefore, the ADC of FIG. 12 takes the maximum value among the outputs of the PT sensors.

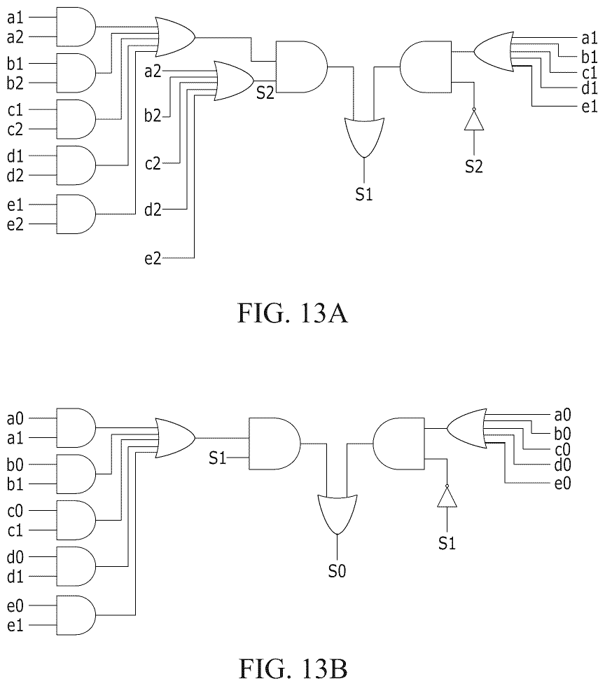

For an example of five PT sensors 910 and ADCs 1110 distributed at five locations (a,b,c,d,e) in the chip 1000, FIG. 13A and FIG. 13B show details of how the encoder 1210 derives the adaptive voltage, for example a maximum value (S<2:0>) at the output of the ADC, where the ADC output is a 3-bit code (a<2:0>, b<2:0>, c<2:0>, d<2:0>, e<2:0>), where a<2:0>stands for the abbreviation of a0, a1, and a2 and where a2 is the most significant bit and a0 is the least significant bit. The encoder first checks to see if any of a2, b2, c2, d2, e2 is a logic “one”, if not, the encoder checks if any of a1, b1, c1, d1, e1 is a one, and so on.

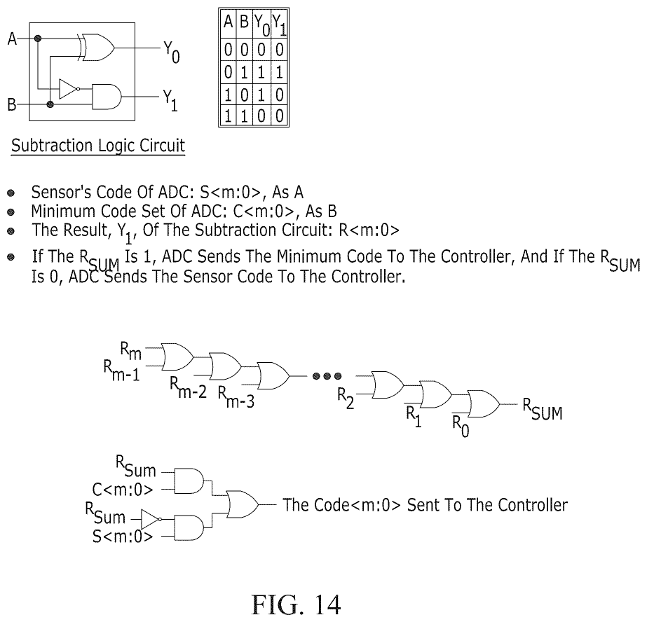

In order to ensure that the selected value is over the minimum value for SRAM operation, which is set in advance, the selected value is compared to the minimum value and the larger value is chosen for the adaptive voltage output, as shown in FIG. 14.

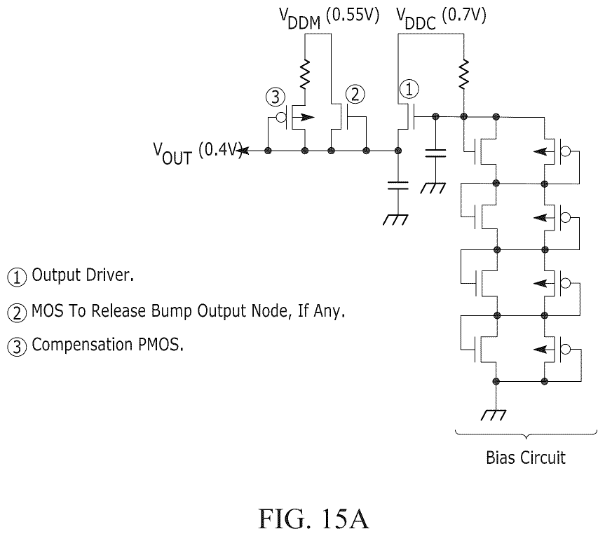

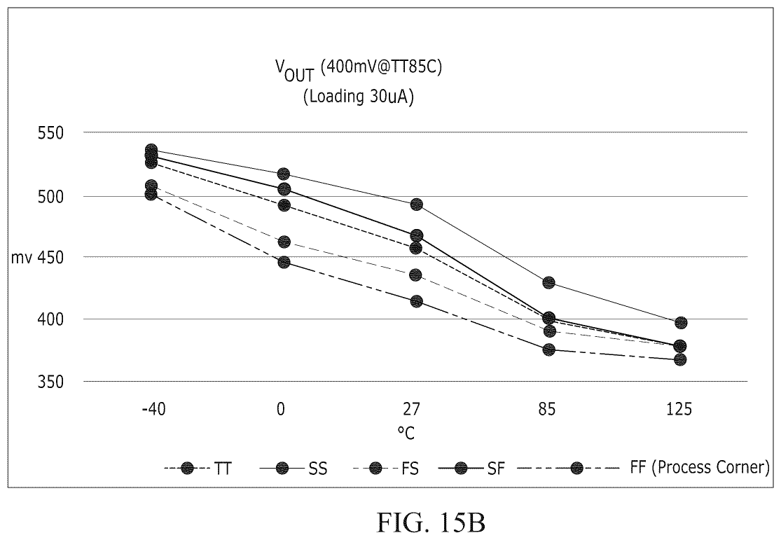

Although an adaptive voltage supply is a robust circuit for use as a power supply, it consumes a large amount of layout area. As described above, AVS1 provides the PE voltage and AVS2 provides the first step word line voltage. Since AVS2 is used for SRAM only, it is desirable to reduce and simplify the layout area of AVS2. Therefore, a simple on-chip low voltage generator is shown in FIG. 15A, to provide, for example, a 0.4V voltage. The voltage generator generates a voltage output that tracks process and temperature variations, inversely. That is, the output of the generator increases with a slow corner, and vice versa. To accomplish this, as shown in FIG. 15A, a voltage divider is provided having a resistor in series with an NMOS/PMOS combination forming a bias circuit. The NMOS/PMOS combination follows the process and temperature variation, proportionally, for tracking process variations of both NMOS and PMOS. A fixed resistance value is maintained relative to the NMOS/PMOS combination when the process or temperature varies. The process and temperature dependency of the on-chip voltage generator of FIG. 15A is shown in FIG. 15B, wherein it will be noted that the output voltage characteristics show a reverse dependency on the process and temperature variation.

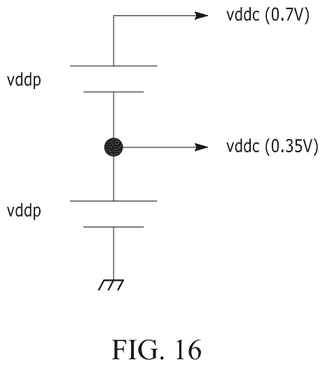

To minimize the number of supply sources and lower the cost of the on-chip SRAM of the present invention, a series connection of two vddp supply sources may be provided, as shown in FIG. 16.

The many features and advantages of the invention are apparent from the detailed specification and, thus, it is intended by the appended claims to cover all such features and advantages of the invention that fall within the true spirit and scope of the invention. Further, since numerous modifications and changes will readily occur to those skilled in the art, it is not desired to limit the invention to the exact construction and operation illustrated and described, and accordingly all suitable modifications and equivalents may be resorted to, falling within the scope of the invention.

What is claimed is:

1. A static random access memory (SRAM) embedded in an at-memory architecture with a processing element (PE) operating at a processing element (PE) domain voltage vddp, comprising:
a bit cell operating at a bit cell voltage vdd; and
a cell vdd selector for generating the bit cell voltage at the PE domain voltage (vdd=vddp) during write operations and generating the bit cell voltage at a standard cell voltage (vdd=vddc) during read operations, where the PE domain voltage is less than the standard cell voltage (vddp<<vddc).

2. The SRAM of claim 1, further comprising a bit line (BL) precharge circuit for setting a bit line (BL) precharge voltage to less than half of the PE domain voltage (vddp/2) during read operations, and to half of the PE domain voltage (vddp/2) during write operations.

3. The SRAM of claim 2, further comprising a negative Vss_cell generator including a charge pump circuit for pulling down a vss voltage of the bit cell to a negative voltage during read operations, and maintaining the vss voltage of the bit cell at 0V during write operations.

4. The SRAM of claim 2, further comprising a read main amp (RMA) and latch disposed at every column on one side of processing element (PE), and data lines (din/dinb) input to the bit line (BL) from an opposite side of processing element (PE), and wherein the cell vdd selector is disposed at every column at the opposite side of processing element (PE).

5. The SRAM of claim 2, wherein the bit line (BL) precharge circuit includes an isolation (ISO) switch for selectively partitioning the bit line (BL) for charge sharing between a far end segment and a near end segment of the bit line (BL) upon assertion of an ISO signal to generate the precharge voltage.

6. The SRAM of claim 5, wherein the isolation (ISO) switch is operable to adjust the bit line (BL) precharge voltage from half the PE domain voltage (vddp/2) during write operations to quarter the PE domain voltage (vddp/4) during read operations by twice short circuiting the two bit line (BL) portions via the isolation (ISO) switch for charge sharing.

7. The SRAM of claim 6, further comprising a word line (WL) driver for generating a two-step word line signal during write operations, wherein a first step is at a word line voltage of vddp, and a second step is at vddc, where vddc>vddp, and generating a single step word line signal at vddp during read operations.

8. The SRAM of claim 7, wherein the word line (WL) driver causes the word line signal to drop to 0V when data (Dout) on the word line (WL) is transferred to the latch, and wherein the bit line (BL) precharge circuit starts precharging the bit line (BL) for reading the data (Dout) on a next assertion of the word line signal.

9. The SRAM of claim 2, wherein the voltage for the processing element (PE) is generated by a first Adaptive Voltage Supply (AVS1) and the word line voltage for the word line (WL) driver is generated by a second Adaptive Voltage Supply (AVS2).

10. The SRAM of claim 9, further comprising a plurality of process and temperature variation sensors (PT sensors) distributed in a chip incorporating the SRAM and processing element (PE), and wherein the output of each PT sensor is applied to an analog-to-digital converter (ADC) whose output is applied to control logic which selects a maximum voltage of the PT sensors for controlling a DC-DC converter to generate the word line voltage.

11. The SRAM of claim 10, wherein the control logic sets a minimum voltage limit for the DC-DC converter.

12. The SRAM of claim 4, further including a cross-coupled NMOS located in the far end segment of the bit line partitioned by the isolation (ISO) switch from the read main amp (RMA) for discharging one of two bit line (BL) portions to ground during read operations.

13. The SRAM of claim 12, wherein a source of the cross-coupled NMOS is pulled down to a negative bias voltage for a period of time and thereafter returned to vss.

14. The SRAM of claim 12, wherein each word line (WL) in the far end segment has a different width than each word line (WL) in the near end segment, and wherein each word line (WL) in the far-end segment is turned-off after the isolation (ISO) switch partitions the bit lines (BL).

15. The SRAM of claim 1, wherein the SRAM comprises a top array and a bottom array, the top array and the bottom array controlled by independently assigned signals.

16. The SRAM of claim 1, further comprising a read main amp (RMA) wherein an activation signal (RMA_EN) of the RMA is activated earlier than a complementary activation signal (RMA_ENB) of the RMA.

17. The SRAM of claim 16, wherein the activation signal (RMA_EN) is activated and then the complementary activation signal (RMA_ENB) is activated when a voltage difference between the bit line pair reaches a predefined voltage.

18. The SRAM of claim 7, wherein the amplitude of the ISO signal for partitioning the bit lines (BL) is from vddp-Vth to vddp during read, and Vddc is fixed during write, being the second step word line voltage.

19. The SRAM of claim 7, wherein the cell_vdd selector performs a pseudo read via a masked write or no write operation in write mode such that a first portion of the WL signal is made the same voltage as during read operations.

20. The SRAM of claim 7, wherein the standard cell voltage (vddc) is generated by a series connection of two PE domain voltage (vddp) power sources.
